(19) United States
(12) Patent Application Publication
(10) Pub. No.: US 2016/0194756 A1
(43) Pub. Date: Jul. 7, 2016

(54) SEMICONDUCTOR PROCESSING APPARATUS HAVING GAS SPRAY UNIT

(71) Applicant: SAMSUNG ELECTRONICS CO., LTD., Suwon-si (KR)

(72) Inventors: Hongtaek LIM, Seoul (KR); Jeonghoon NAM, Suwon-si (KR); Chul PARK, Yongin-si (KR); Youngchae SEO, Suwon-si (KR); Jaihyung WON, Seoul (KR); Seungmoo LEE, Suwon-si (KR); Donghoon HAN, Seoul (KR)

(21) Appl. No.: 14/972,598

(22) Filed: Dec. 17, 2015

(30) Foreign Application Priority Data
Jan. 2, 2015 (KR) 10-2015-0000181

(51) Int. Cl. C23C 16/455; C23C 16/44

(52) U.S. Cl. CPC C23C 16/45512; C23C 16/45565; C23C 16/45591; C23C 16/45574; C23C 16/4412

(57) ABSTRACT

A semiconductor processing apparatus includes a susceptor supporting a processing target, a gas box spaced apart from the susceptor, the gas box including a concave region facing an upper surface of the processing target, and an inclined surface at an outer side of the concave region, an inclination angle of the inclined surface of the gas box relative to an upper surface of the susceptor is more than 10° and less than 35°, and a shower head within the concave region of the gas box.

### CROSS-REFERENCE TO RELATED APPLICATION

Korean Patent Application No. 10-2015-0000181, filed on Jan. 2, 2015, in the Korean Intellectual Property Office, and entitled: “Semiconductor Processing Apparatus Having Gas Spray Unit,” is incorporated by reference herein in its entirety.

### BACKGROUND

1. Field

Embodiments relate to a semiconductor processing apparatus having a gas spray unit configured to spray a processing gas onto a processing target.

2. Description of the Related Art

Semiconductor processing apparatuses include a deposition system for forming a layer on a processing target using a processing gas. The semiconductor processing apparatus may include a susceptor configured to support the processing target and a gas spray unit configured to spray the processing gas onto the processing target. The gas spray unit may include a shower head including gas injectors and a gas box configured to transfer the processing gas to the shower head. Various studies are being carried out in order to decrease a thickness variation of a layer formed on the processing target in the semiconductor processing apparatus.

### SUMMARY

Embodiments provide a semiconductor processing apparatus capable of minimizing a thickness variation of a layer formed on a processing target.

Other embodiments provide a semiconductor processing apparatus capable of preventing an abrupt change in a flow rate of a processing gas on the processing target.

In accordance with an aspect of the embodiments, a semiconductor processing apparatus includes a susceptor supporting a processing target, a gas box spaced apart from the susceptor, the gas box including a concave region facing an upper surface of the processing target, and an inclined surface at an outer side of the concave region, an inclination angle of the inclined surface of the gas box relative to an upper surface of the susceptor is more than 10° and less than 35°, and a shower head within the concave region of the gas box.

A horizontal length of the concave region of the gas box may be smaller than a horizontal length of the processing target.

A highest level of the inclined surface of the gas box may be the same as a level of a lower surface of the shower head.

The shower head may include gas injectors which are arranged along the processing target.

In accordance with another aspect of the embodiments, a semiconductor processing apparatus includes a susceptor configured to support the processing target, and a gas spray unit configured to spray a processing gas onto the processing target. The gas spray unit is spaced apart from the susceptor. The gas spray unit includes an inclined surface facing an edge of the processing target and gas injectors disposed at an inner side of the inclined surface. An inclination angle of the inclined surface of the gas spray unit is more than 10° but less than 35°.

The inclination angle of the inclined surface of the gas spray unit may be in a range of 15° to 30°.

The semiconductor processing apparatus may further include a baffle assembly disposed at an outer side of the gas spray unit. The baffle assembly may include a slit extending along a side surface of the gas spray unit

The semiconductor processing apparatus may further include a process chamber disposed at an outer side of the baffle assembly. The process chamber may include an exhaust duct extending along the baffle assembly.

The semiconductor processing apparatus may further include an exhaust unit disposed at an outer side of the process chamber. The exhaust unit may be directly connected to the exhaust duct of the process chamber.

In accordance with still another aspect of the embodiments, a semiconductor processing apparatus includes a susceptor for supporting the wafer, a shower head which is disposed above the susceptor and includes gas injectors, and a gas box which is spaced apart from the susceptor and includes a concave region for accommodating the shower head and an inclined surface disposed at an outer side of the concave region. The inclined surface of the gas box may have an inclination angle of more than 10° but less than 35°.

In accordance with yet another aspect of the embodiments, a semiconductor processing apparatus includes a susceptor supporting a processing target, a gas box spaced apart from the susceptor, the gas box including a concave region facing an upper surface of the susceptor, and an inclined surface extending from an edge of the concave region toward the susceptor, an inclination angle of the inclined surface of the gas box relative to the upper surface of the susceptor is more than 10° and less than 35°, and a shower head within the concave region of the gas box.

The concave region may include a mixing region overlapping a center of the susceptor; and a seating region surrounding an outer edge of the mixing region, the shower head being attached to the seating region at a predetermined distance from the mixing region.

The inclined surface of the gas box may extend from a bottom of the shower head toward an outer edge of the susceptor.

The inclined surface of the gas box may be entirely external to the shower head.

The apparatus may further include a plurality of gas paths through the gas box, nozzles sprays corresponding to the gas paths, the nozzle sprays being on a surface of the mixing region of the concave region, and a plurality of gas injectors through the shower head, the plurality of gas injectors overlapping the mixing region of the concave region.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic view of a semiconductor processing apparatus in accordance with an embodiment;

FIGS. 2A and 2B illustrate partial views of the semiconductor processing apparatus according to the embodiment of FIG. 1;

FIG. 3 illustrates an enlarged view of a region P of FIG. 1;

FIGS. 4A and 4B illustrate graphs of changes in wall shear stress according to a figuration of a gas box in the semiconductor processing apparatus in accordance with an embodiment;

FIG. 5A illustrates a susceptor and a gas spray unit of a semiconductor processing apparatus in accordance with another embodiment;

FIG. 5B illustrates an enlarged view of a region R of FIG. 5A; and

FIG. 6 illustrates a schematic view of a semiconductor processing apparatus in accordance with still another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer (i.e., element) is referred to as being “between” two layers, it can be the only layer between the two layers, or one or more intervening layers may also be present. Like reference numerals refer to like elements throughout.

It will be understood that the terms “first,” “second,” etc. are used herein to describe various elements and used for the purpose of distinguishing one element from another element. Thus, without deviating from the scope of the embodiments, a first element and a second element may be arbitrarily named for the sake of convenience for those skilled in the art.

The terminology used herein is only intended to describe specific embodiments and is not intended to limit. For example, the singular forms “a,” “an,” and “the” are intended to include the plural forms as well, unless the context clearly indicates otherwise. Also, it will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment

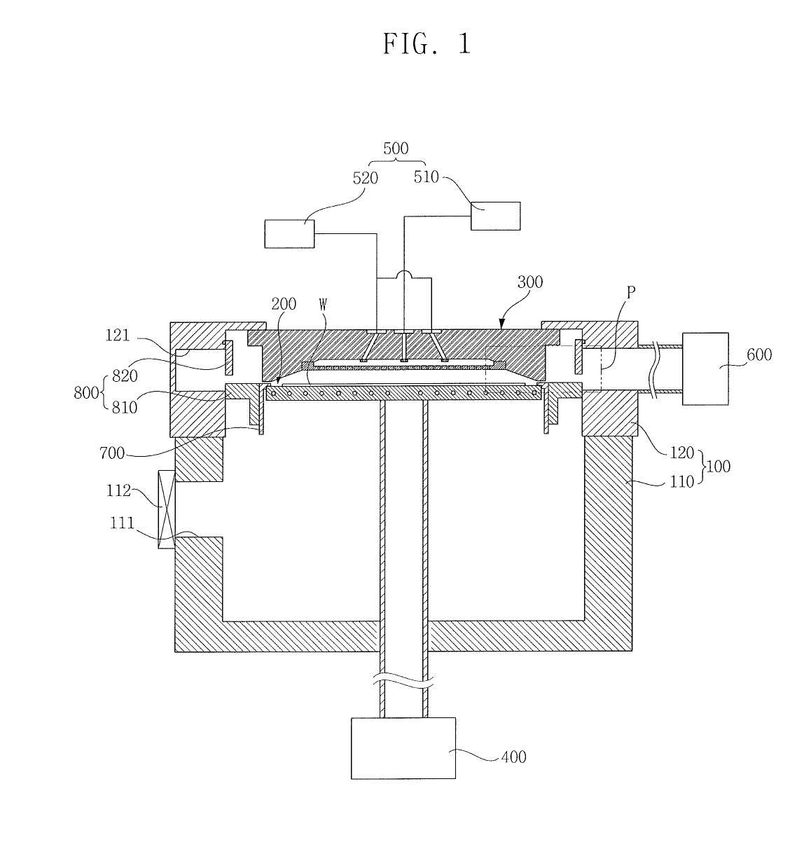

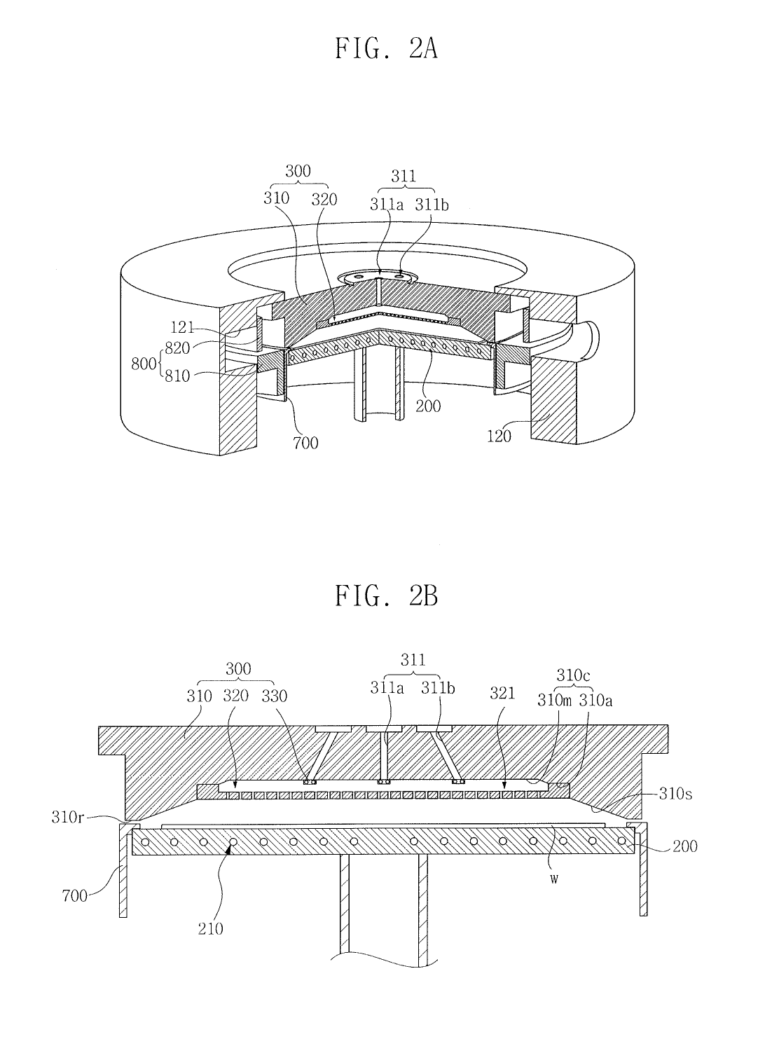

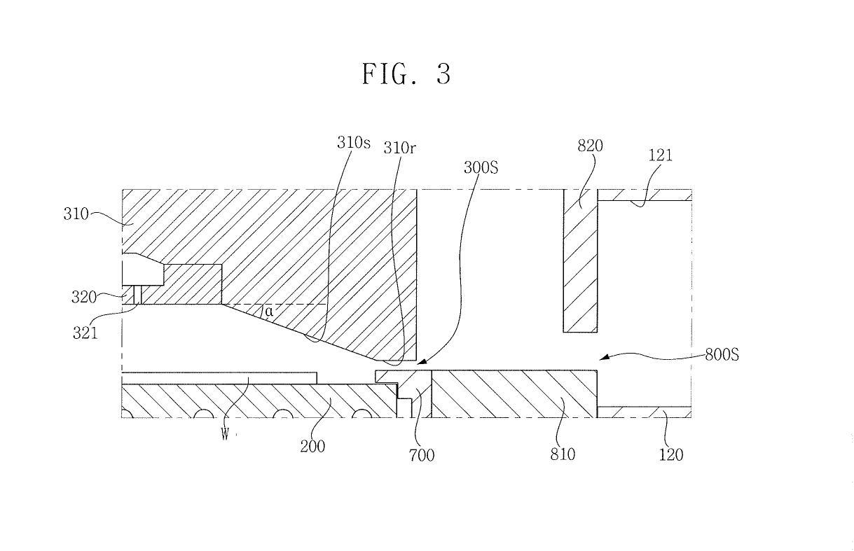

FIG. 1 is a view schematically illustrating a semiconductor processing apparatus in accordance with an embodiment. FIGS. 2A and 2B are views partially illustrating the semiconductor processing apparatus according to the embodiment of FIG. 1. FIG. 3 is an enlarged view illustrating a region P of FIG. 1.

Referring to FIGS. 1, 2A, 2B and 3, a semiconductor processing apparatus according to an embodiment may include a process chamber 100, a susceptor 200, a gas spray unit 300, a susceptor driving unit 400, a gas supply unit 500, an exhaust unit 600, a cover element 700, and a baffle assembly 800.

The process chamber 100 may provide a space where a designed process is performed. For example, the process chamber 100 may provide a space for forming a layer on a processing target W. The processing target W may include a wafer.

The process chamber 100 may include a lower chamber 110 and an upper chamber 120.

The lower chamber 110 may provide a space for loading or unloading the processing target W. The lower chamber 110 may include a loading/unloading port 111 and a gate valve 112. The processing target W may be loaded into an inside of the process chamber 100 through the loading/unloading port 111 of the lower chamber 110. When the designed process is finished, the processing target W may be unloaded from the process chamber 100 through the loading/unloading port 111 of the lower chamber 110. The loading/unloading port 111 may be opened and closed by the gate valve 112.

The upper chamber 120 may provide a space where a processing gas is sprayed onto the processing target W. For example, the layer on the processing target W may be formed by the designed process in an inside of the upper chamber 120.

The upper chamber 120 may be disposed above the lower chamber 110. An inner space of the upper chamber 120 may be connected to an inner space of the lower chamber 110. The processing target W loaded into the lower chamber 110 is transferred to the upper chamber 120, and then the processing gas may be sprayed onto the processing target W.

The upper chamber 120 may include an exhaust duct 121. The exhaust duct 121 may serve as an exhaust path for the processing gas. For example, the processing gas sprayed into the inside of the upper chamber 120 may be exhausted to the outside of the upper chamber 120 through the exhaust duct 121.

The exhaust duct 121 may extend along a sidewall of the upper chamber 120. For example, the exhaust duct 121 may be disposed within the sidewall of the upper chamber 120, e.g., to completely surround the upper chamber 120 (FIG. 2A).

The exhaust duct 121 of the process chamber 100 may be directly connected to the exhaust unit 600. For example, the exhaust unit 600 may be disposed at an outer side of the upper chamber 120.

The susceptor 200 may support the processing target W. The susceptor 200 may be moved by the susceptor driving unit 400. For example, the susceptor driving unit 400 may move the susceptor 200 from the lower chamber 110 to the upper chamber 120. The processing target W loaded into the lower chamber 110 may be transferred to the upper chamber 120 by the susceptor driving unit 400. When the designed process is finished, the processing target W may be transferred to the lower chamber 110 by the susceptor driving unit 400.

The susceptor 200 may include a heater 210 (FIG. 2B). While the designed process is performed, the processing target W may be heated by the heater 210.

The gas spray unit 300 may spray the processing gas onto the processing target W. The gas spray unit 300 may be disposed above the susceptor 200. The gas spray unit 300 may be spaced apart from the susceptor 200 elevated by the susceptor driving unit 400, e.g., a space may be defined between the gas spray unit 300 and an uppermost position of the susceptor 200 (FIG. 1). For example, the gas spray unit 300 may be disposed within the upper chamber 120. The gas spray unit 300 may be coupled to an upper end of the upper chamber 120.

As illustrated in FIG. 2A-2B, the gas spray unit 300 may include a gas box 310, a shower head 320, and a spray nozzle 330.

The gas box 310 may transfer the processing gas to the shower head 320. The gas box 310 may include a gas path 311. The gas path 311 of the gas box 310 may be connected to the gas supply unit 500.

The semiconductor processing apparatus according to the embodiment may use two types of processing gases. The gas supply unit 500 may include a first gas supply unit 510 and a second gas supply unit 520. The gas path 311 of the gas box 310 may include a first gas path 311a and a second gas path 311b. The first gas path 311a may be connected to the first gas supply unit 510. The second gas path 311b may be connected to the second gas supply unit 520. The number of the second gas paths 311b may be different from the number of the first gas paths 311a.

The gas box 310 may include a concave region 310c, an inclined surface 310s, and a rim surface 310r.

The concave region 310c may face the processing target W. The concave region 310c may be disposed within the surface of the gas box 310 which faces the susceptor 200. For example, the concave region 310c may be disposed within a lower surface of the gas box 310, e.g., the lower surface of the gas box 310 facing the susceptor 200 may be concave and curve away from the susceptor 200.

A horizontal length of the concave region 310c may be smaller than a horizontal length of the processing target W. For example, a diameter of the concave region 310c may be smaller than a diameter of the processing target W.

The concave region 310c may include a seating region 310a and a mixing region 310m. The mixing region 310m may be disposed at an inner side of the seating region 310a. The seating region 310a may surround the mixing region 310m. The mixing region 310m may be disposed in the middle of the concave region 310c.

The mixing region 310m may be a region which is recessed into the inside of the gas box 310 from the seating region 310a. For example, the lowest level of the mixing region 310m may be the same as the highest level of the seating region 310a.

The inclined surface 310s may be disposed at an outer side of the concave region 310c. The inclined surface 310s may extend along the edge of the concave region 310c, e.g., the inclined surface 310s may extend along a periphery of the concave region 310c. The concave region 310c may be disposed at an inner side of the inclined surface 310s. For example, the inclined surface 310s may face an edge of the processing target W.

A vertical distance between the inclined surface 310s of the gas box 310 and the susceptor 200 may be reduced toward an edge of the susceptor 200, e.g., a distance between the inclined surface 310s and the susceptor 200 may decrease as a distance from a center of the susceptor 200 is increased. For example, a diameter of the inclined surface 310s may increase gradually away from the concave region 310c. For example, a minimum diameter of the inclined surface 310s may be in a range of about 0.84 times to about 0.90 times a diameter of the processing target W. For example, a maximum diameter of the inclined surface 310s may be in a range of about 1.10 times to about 1.14 times the diameter of the processing target W.

The inclined surface 310s may be continuous with a sidewall of the concave region 310c. For example, a highest level of the inclined surface 310s may be the same as a lowest level of the concave region 310c.

The rim surface 310r may be disposed at an outer side of the inclined surface 310s. The rim surface 310r may extend along an edge of the inclined surface 310s. For example, a horizontal length of the gas box 310 may be greater than a horizontal length of the susceptor 200. The rim surface 310r of the gas box 310 may face the edge of the susceptor 200. The rim surface 310r of the gas box 310 may be parallel to an upper surface of the susceptor 200.

The shower head 320 may spray the processing gas transferred by the gas box 310. The shower head 320 may be disposed within the concave region 310c of the gas box 310. For example, a horizontal length of the shower head 320 may be smaller than the horizontal length of the processing target W.

The shower head 320 may be coupled to the seating region 310a of the concave region 310c. For example, an edge of the shower head 320 may be directly in contact with the seating region 310a of the gas box 310.

The shower head 320 may be spaced apart from the mixing region 310m of the gas box 310. For example, the processing gas transferred by the first gas path 311a and the processing gas transferred by the second gas path 311b may be mixed in a space between the shower head 320 and the mixing region 310m.

A lower surface of the shower head 320 may face an upper surface of the processing target W. The lower surface of the shower head 320 may be parallel to the upper surface of the processing target W.

A vertical length of a side surface of the shower head 320 may be the same as a vertical length of a side wall of the seating region 310a of the concave region 310c. A level of the lower surface of the shower head 320 may be the same as a lowest level of the seating region 310a of the concave region 310c. The level of the lower surface of the shower head 320 may be the same as the lowest level of the concave region 310c of the gas box 310. The highest level of the inclined surface 310s of the gas box 310 may be the same as the level of the lower surface of the shower head 320. For example, the lower surface of the shower head 320 may be continuous with the inclined surface 310s of the gas box 310.

A vertical distance between the shower head 320 and the processing target W may be proportional to a vertical distance between the susceptor 200 and the rim surface 310r of the gas box 310. For example, the vertical distance between the susceptor 200 and the rim surface 310r of the gas box 310 may be in a range of about 0.10 times to about 0.16 times the vertical distance between the shower head and the processing target W.

The shower head 320 may include gas injectors 321 (FIG. 3). The gas injectors 321 may extend toward the processing target W, e.g., the gas injectors 321 may extend through the shower head 320 toward the processing target W. For example, the gas injectors 321 may extend in a vertical direction through the shower head 320, and may have a predetermined width in the horizontal direction. The gas injectors 321 may be arranged along the upper surface of the processing target W.

The gas injectors 321 may be disposed under the mixing region 310m, e.g., a region of the shower head 320 including the gas injectors 321 and the mixing region 310m may overlap each other. For example, a horizontal length of the mixing region 310m may be greater than a maximum horizontal length of the region of the showerhead 320 including gas injectors 321, e.g., a horizontal length of the mixing region 310m may be greater than a distance between two opposite, most-outer gas injectors 321. The maximum horizontal length of the gas injectors 321 may be proportional to the horizontal length of the processing target W. For example, a maximum diameter of the region of the showerhead 320 including the gas injectors 321 may be in a range of about 0.6 times to about 0.7 times the diameter of the processing target W.

The spray nozzle 330 may be connected to the gas path 311 of the gas box 310. The spray nozzle 330 may be disposed between the gas box 310 and the shower head 320. For example, the spray nozzle 330 may be disposed within the mixing region 310m of the gas box 310. The processing gas transferred by the gas path 311 of the gas box 310 may be sprayed onto a space between the shower head 320 and the mixing region 310m by the spray nozzle 330.

The cover element 700 may cover the edge of the susceptor 200 elevated by the susceptor driving unit 400. A position of the susceptor 200 in the upper chamber 120 may be determined by the cover element 700, e.g., the cover element 700 may prevent the susceptor 200 from being elevated further.

An upper surface of the cover element 700 may face the rim surface 310r of the gas box 310 (FIG. 2B). The upper surface of the cover element 700 may be spaced apart from the rim surface 310r of the gas box 310. The processing gas sprayed by the gas spray unit 300 may be exhausted through a space 300S between the cover element 700 and the gas box 310 (FIG. 3).

The space 300S between the cover element 700 and the gas box 310 may be aligned horizontally with the exhaust duct 121 of the process chamber 100. The space 300S between the cover element 700 and the gas box 310 may be disposed between a lowest level and a highest level of the exhaust duct 121 of the process chamber 100, e.g., the space 300S may provide a fluid communication path between the exhaust duct 121 and a space above the processing target W and.

The baffle assembly 800 may disperse a flow of the processing gas exhausted through the space 300S between the cover element 700 and the gas box 310. The baffle assembly 800 may prevent an exhaust velocity of the processing gas from being changed according to a position of the exhaust unit 600.

The baffle assembly 800 may be disposed at an outer side of the gas spray unit 300. The baffle assembly 800 may include a slit 800S (FIG. 3). The slit 800S of the baffle assembly 800 may extend along a side surface of the gas spray unit 300. For example, the baffle assembly 800 may include a lower baffle 810 and an upper baffle 820 which are spaced apart from each other.

The slit 800S of the baffle assembly 800 may be aligned horizontally with the space 300S between the cover element 700 and the gas box 310, e.g., the slit 800S and the space 300S may be in fluid communication. The slit 800S of the baffle assembly 800 may be at a height between the susceptor 200 and the gas spray unit 300. For example, the lower baffle 810 may be disposed on a side surface of the susceptor 200 and the upper baffle 820 may be disposed on the side surface of the gas spray unit 300.

A size, e.g., a vertical height in FIG. 3, of the slit 800S of the baffle assembly 800 may be larger than a size of the space 300S between the cover element 700 and the gas box 310. For example, the space 300S between the cover element 700 and the gas box 310 may be disposed between a lowest level and a highest level of the slit 800S of the baffle assembly 800.

The slit 800S of the baffle assembly 800 may be aligned horizontally with the exhaust duct 121 of the process chamber 100. The size, e.g., the vertical height in FIG. 3, of the slit 800S of the baffle assembly 800 may be smaller than a size of the exhaust duct 121 of the process chamber 100. For example, the slit 800S of the baffle assembly 800 may be disposed between the lowest level and the highest level (along the vertical direction) of the exhaust duct 121 of the process chamber 100.

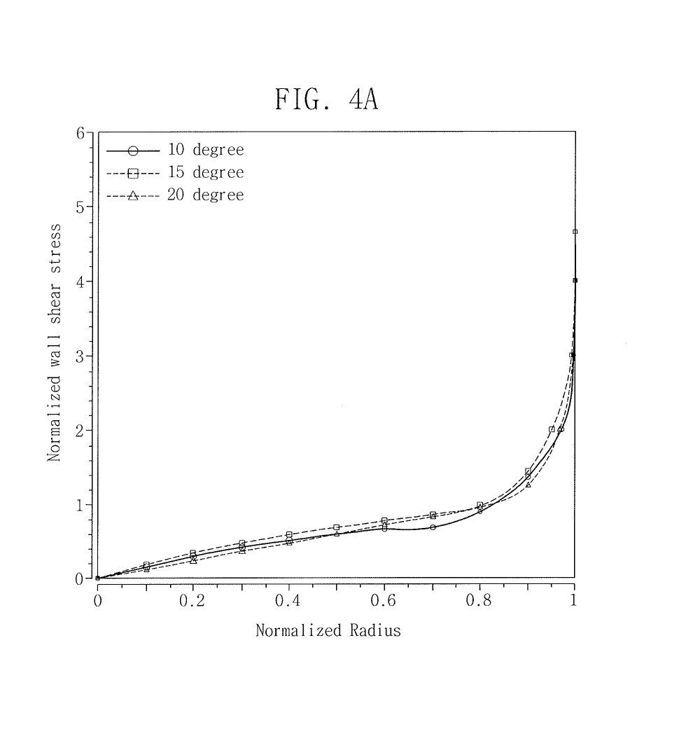

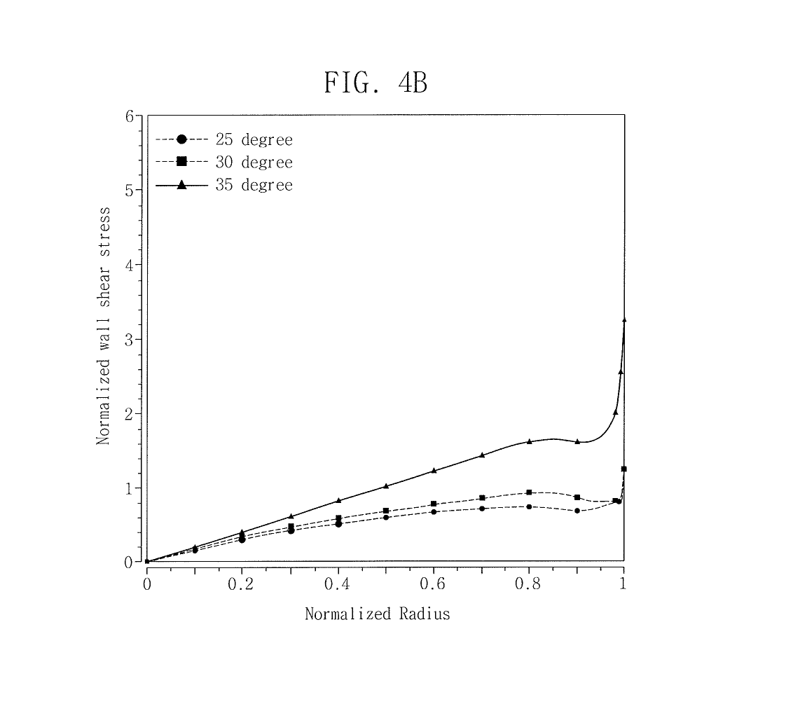

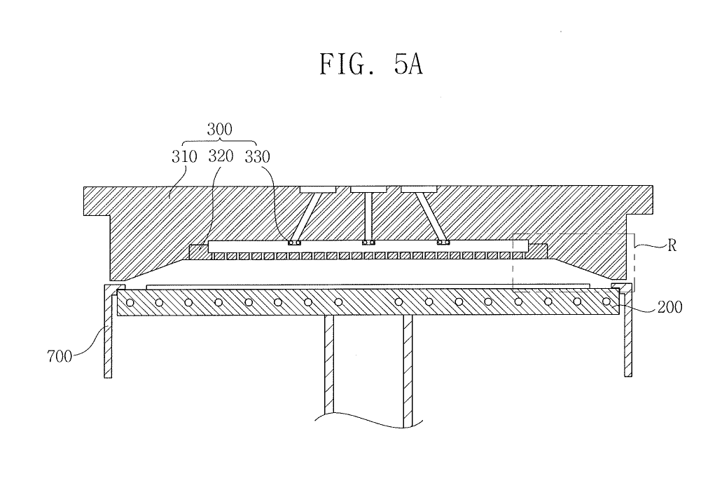

FIGS. 4A and 4B are graphs showing changes in normalized wall shear stress according to an inclination angle α of the inclined surface 310s of the gas box 310 in the semiconductor processing apparatus in accordance with the embodiment. Here, a horizontal axis of the graph illustrated in FIGS. 4A and 4B are a normalized radius of the processing target W. Further, the inclination angle α refers to an angle between the inclined surface 310s and an extension of a bottom of the shower head 320 (FIG. 3). The bottom of the shower head 320 may be parallel to the upper surface of the susceptor, i.e., the inclination angle α refers to an angle between the inclined surface 310s and the upper surface of the susceptor 200.

Referring to FIGS. 4A and 4B, when the inclination angle of the inclined surface 310s of the gas box 310 is in a range of about 15° to about 35°, the graph has an inflection point occurring at a location where the normalized radius of the processing target W is in a range of about 0.8 to about 0.9. However, when the inclination angle of the inclined surface 310s of the gas box 310 is decreased to about 10°, the graph has an inflection point occurring at a location where the normalized radius of the processing target W is in a range of about 0.6 to about 0.7.

The inflection point in the graph showing the normalized wall shear stress means that an abrupt change of flow is generated. That is, in the semiconductor processing apparatus according to the embodiment, when the inclination angle of the inclined surface 310s of the gas box 310 is decreased to 10°, a location, where a flow rate of the processing gas is abruptly changed, relatively moves in an inner direction of the processing target W.

The abrupt change in the flow rate of the processing gas may cause a rapid change in a thickness of a layer formed on the processing target W. That is, when a location of an abrupt change of flow rate of the processing gas above the processing target W moves to the left along the horizontal axis of the graph of FIGS. 4A and 4B (smaller radius), a thickness variation of a layer formed on the processing target W may be increased. Therefore, in the semiconductor processing apparatus according to the embodiment, the inclination angle of the inclined surface 310s of the gas box 310 is larger than 10°, e.g., larger than 15°.

Furthermore, when the inclination angle of the inclined surface 310s of the gas box 310 is increased to 35°, the inclination angle in the graph showing the normalized wall shear stress according to the position on the processing target W is relatively increased. An inclination in the graph showing the normalized wall shear stress according to the position on the processing target W means a velocity change amount of the processing gas according to the position on the processing target. That is, when the inclination angle of the inclined surface 310s of the gas box 310 is increased to about 35°, the processing gas moves relatively rapidly on the processing target W. When the flow rate of the processing gas is increased, a difference in thicknesses of layers which are deposited at two positions adjacent to each other on the processing target W may be great. Therefore, in the semiconductor processing apparatus according to the embodiment, the inclination angle of the inclined surface 310s of the gas box 310 is smaller than 35°, e.g., smaller than 30°.

As a result, the semiconductor processing apparatus according to the embodiment may include the concave region 310c accommodating the shower head 320 having a diameter smaller than a diameter of the processing target W, and the inclined surface 310s disposed at an outer side of the concave region 310c, wherein the inclination angle α of the inclined surface 310s (FIG. 3) is limited to more than 10° but less than 35°, e.g., in a range of about 15° to about 30°.

Therefore, the abrupt change in the flow rate of a processing gas on the processing target W may be prevented in the semiconductor processing apparatus according to the embodiment. Furthermore, in the semiconductor processing apparatus according to the embodiment, the processing gas may have a relatively low flow rate on the processing target W. Thus, the thickness variation of the layer formed on the processing target W may be minimized in the semiconductor processing apparatus according to the embodiment.

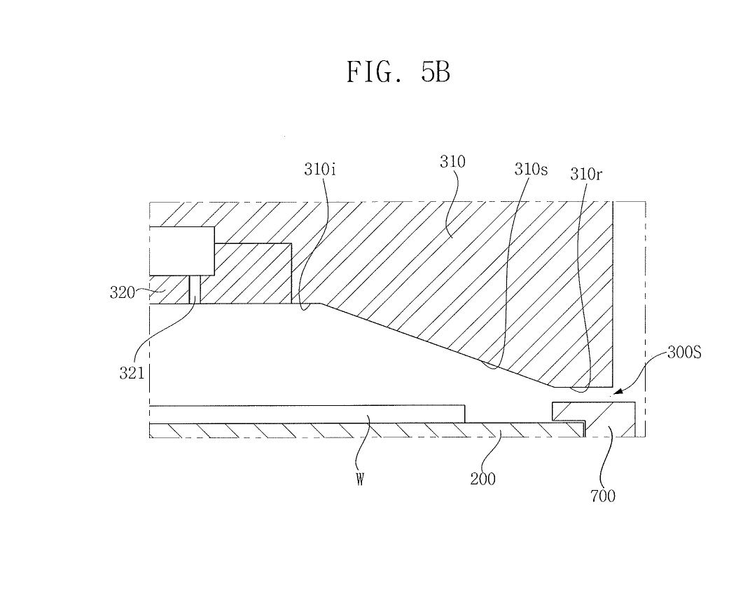

FIG. 5A shows a susceptor and a gas spray unit of a semiconductor processing apparatus in accordance with an embodiment. FIG. 5B is an enlarged view of a region R of FIG. 5A.

Referring to FIGS. 5A and 5B, the gas spray unit 300 of the semiconductor processing apparatus according to an embodiment may include the gas box 310, the shower head 320 having gas injectors 321, and the spray nozzle 330 disposed between the gas box 310 and the shower head 320.

The gas box 310 may include the inclined surface 310s which is disposed at the outer side of the shower head 320 and the rim surface 310r which is disposed at the outer side of the inclined surface 310s. The inclined surface 310s of the gas box 310 may not be directly connected to a lower surface of the shower head 320. For example, the gas box 310 may further include an intermediate surface 310i disposed between the inclined surface 310s and the lower surface of the shower head 320.

The intermediate surface 310i of the gas box 310 may be continuous with the inclined surface 310s of the gas box 310. The intermediate surface 310i of the gas box 310 may be continuous with the lower surface of the shower head 320. A level of the intermediate surface 310i of the gas box 310 may be the same as a level of the lower surface of the shower head 320. For example, the intermediate surface 310i of the gas box 310 may be parallel to an upper surface of the processing target W.

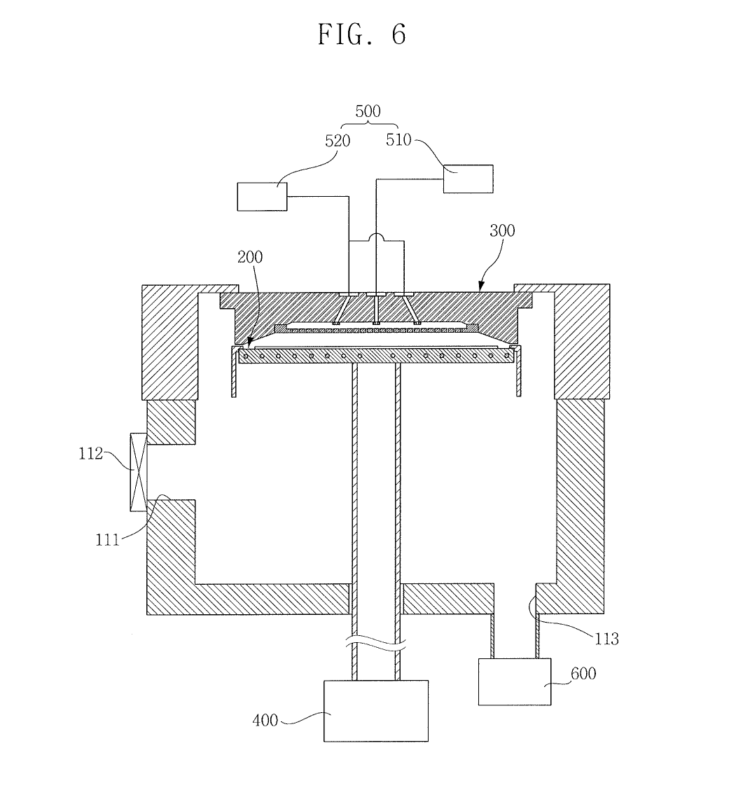

FIG. 6 is a view schematically illustrating a semiconductor processing apparatus in accordance with an embodiment.

Referring to FIG. 6, the semiconductor processing apparatus according to an embodiment may include the process chamber 100, the susceptor 200, the gas spray unit 300, the susceptor driving unit 400, the gas supply unit 500, the exhaust unit 600, and the cover element 700. The gas supply unit 500 may include the first gas supply unit 510 and the second gas supply unit 520.

The process chamber 100 may include the lower chamber 110 and the upper chamber 120. The lower chamber 110 may include the loading/unloading port 111, the gate valve 112, and an exhaust port 113.

A processing gas sprayed by the gas spray unit 300 may be exhausted through the exhaust port 113 of the lower chamber 110. The exhaust port 113 of the lower chamber 110 may be connected to the exhaust unit 600. For example, the exhaust unit 600 may be disposed at an outer side of the lower chamber 110.

According to the embodiment, an abrupt change in a flow rate of a processing gas on a processing target may be prevented in the semiconductor processing apparatus. Therefore, a thickness variation of a layer formed on the processing target may be minimized in the semiconductor processing apparatus according to the embodiment.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor processing apparatus, comprising:
a susceptor supporting a processing target;
a gas box spaced apart from the susceptor, the gas box including:
a concave region facing an upper surface of the processing target, and
an inclined surface at an outer side of the concave region, an inclination angle of the inclined surface of the gas box relative to an upper surface of the susceptor is more than 10° and less than 35°; and
a shower head within the concave region of the gas box.

2. The apparatus as claimed in claim 1, wherein a horizontal length of the concave region of the gas box is smaller than a horizontal length of the processing target.

3. The apparatus as claimed in claim 1, wherein a highest level of the inclined surface of the gas box is the same as a level of a lower surface of the shower head.

4. The apparatus as claimed in claim 3, wherein the level of the lower surface of the shower head is the same as a lowest level of the concave region of the gas box.

5. The apparatus as claimed in claim 1, wherein the shower head includes gas injectors arranged along the processing target.

6. The apparatus as claimed in claim 1, wherein the gas box further includes a rim surface at an outer side of the inclined surface, the rim surface facing an edge of the susceptor.

7. A semiconductor processing apparatus, comprising:
a susceptor to support a processing target; and
a gas spray unit to spray a processing gas onto the processing target, the gas spray unit being spaced apart from the susceptor,
wherein the gas spray unit includes an inclined surface facing an edge of the processing target and gas injectors at an inner side of the inclined surface, and
wherein an inclination angle of the inclined surface of the gas spray unit relative to an upper surface of the susceptor is more than 10° and less than 35°.

8. The apparatus as claimed in claim 7, wherein the inclination angle of the inclined surface of the gas spray unit is in a range of about 15° to about 30°.

9. The apparatus as claimed in claim 7, further comprising a baffle assembly at an outer side of the gas spray unit, the baffle assembly including a slit extending along a side surface of the gas spray unit.

10. The apparatus as claimed in claim 9, wherein a size of the slit of the baffle assembly is larger than a size of a space between the susceptor and the gas spray unit.

11. The apparatus as claimed in claim 9, further comprising a process chamber at an outer side of the baffle assembly, the process chamber including an exhaust duct extending along the baffle assembly.

12. The apparatus as claimed in claim 11, wherein the exhaust duct of the process chamber is within a sidewall of the process chamber.

13. The apparatus as claimed in claim 11, wherein the slit of the baffle assembly is between a lowest level and a highest level of the exhaust duct of the process chamber.

14. The apparatus as claimed in claim 11, further comprising an exhaust unit at an outer side of the process chamber, the exhaust unit being directly connected to the exhaust duct of the process chamber.

15. The apparatus as claimed in claim 7, further comprising a cover element spaced apart from the gas spray unit, the cover element covering an edge of the susceptor.

16. A semiconductor processing apparatus, comprising:
a susceptor supporting a processing target;
a gas box spaced apart from the susceptor, the gas box including:
a concave region facing an upper surface of the susceptor, and
an inclined surface extending from an edge of the concave region toward the susceptor, an inclination angle of the inclined surface of the gas box relative to the upper surface of the susceptor is more than 10° and less than 35°; and
a shower head within the concave region of the gas box.

17. The apparatus as claimed in claim 16, wherein the concave region includes:
a mixing region overlapping a center of the susceptor; and
a seating region surrounding an outer edge of the mixing region, the shower head being attached to the seating region at a predetermined distance from the mixing region.

18. The apparatus as claimed in claim 17, wherein the inclined surface of the gas box extends from a bottom of the shower head toward an outer edge of the susceptor.

19. The apparatus as claimed in claim 18, wherein the inclined surface of the gas box is entirely external to the shower head.

20. The apparatus as claimed in claim 17, further comprising:
a plurality of gas paths through the gas box;
nozzles sprays corresponding to the gas paths, the nozzle sprays being on a surface of the mixing region of the concave region; and
a plurality of gas injectors through the shower head, the plurality of gas injectors overlapping the mixing region of the concave region.
